(19) United States
(12) Patent Application Publication
(10) Pub. No.: US 2025/0026134 A1
(43) Pub. Date: Jan. 23, 2025

(54) LIGHT IRRADIATING APPARATUS

(71) Applicant: HOYA CORPORATION, Tokyo (JP)

(72) Inventor: Norio KOBAYASHI, Tokyo (JP)

(73) Assignee: HOYA CORPORATION, Tokyo (JP)

(21) Appl. No.: 18/776,534

(22) Filed: Jul. 18, 2024

(30) Foreign Application Priority Data
Jul. 21, 2023 (JP) 2023-118894

(51) Int. Cl. B41J 11/00; H05K 1/02

(52) U.S. Cl. CPC B41J 11/00218; B41J 11/00214; H05K 1/0204; H05K 2201/066; H05K 2201/10106

(57) ABSTRACT

A light irradiating apparatus comprises: a light source module which includes a board and a light-emitting element mounted on a first surface of the board; a heat sink which is provided in contact with a second surface of the board; a circuit board or circuit wiring which is electrically connected to the light source module; and a housing which has a first space which houses the heat sink and a second space which houses the circuit board or circuit wiring, wherein the housing is provided with a first opening which connects the first space and an outside of the housing, a second opening which connects the second space and the outside of the housing, and a third opening which connects the first space and the second space.

### TECHNICAL FIELD

The present disclosure relates to subject matter contained in Japanese Patent Application No. 2023-118894 (filed on Jul. 21, 2023) which is expressly incorporated herein by reference in its entirety.

The present invention relates to a light irradiating apparatus which irradiates an irradiation target with light, and particularly relates to a light irradiating apparatus including a light source module and a heat sink for cooling the light source module inside a housing.

### BACKGROUND ART

As an ink for printing, ultraviolet curable inks which are cured by irradiation of ultraviolet light have conventionally been used. In addition, as sealants for FPDs (Flat Panel Displays) such as liquid crystal panels and organic EL (Electro Luminescence) panels, ultraviolet curable resins are used. For curing such ultraviolet curable inks and ultraviolet curable resins, ultraviolet light irradiating apparatuses which irradiate ultraviolet curable inks and ultraviolet curable resins with ultraviolet light have been used. Particularly, in the application of printing and FPDs, since it is necessary to irradiate an irradiation region having a wide rectangular shape with ultraviolet light having a high irradiation intensity, light irradiating apparatuses in which a large number of light-emitting elements are arrayed on a board to face the irradiation region are used.

In such a light irradiating apparatus using a large number of light-emitting elements, such a problem occurs in which the temperature is increased by the heat generated by the light-emitting elements, so that the luminous efficiency of the light-emitting elements significantly decreases. For this reason, a configuration is employed in which a heat-dissipating member such as a heat sink is provided in tight contact with a board, and a refrigerant such as a cooling water is caused to flow through a flow passage formed inside the heat-dissipating member to forcibly dissipate heat generated by the light-emitting elements (for example, Patent Literature 1).

The light irradiating apparatus of Patent Literature 1 includes a housing which houses a light irradiating device in which a plurality of light-emitting elements are disposed, a drive board for driving the plurality of light-emitting elements, a heat-dissipating member, and a cooling pipe for allowing a refrigerant to flow through the heat-dissipating member. The light irradiating device includes a board which includes an internal electric wiring and the plurality of light-emitting elements disposed on the board and functions as an ultraviolet light irradiation source. In addition, the board of the light irradiating device is bonded to one main surface of the heat-dissipating member, and the drive board is bonded to the other main surface of the heat-dissipating member, so that heat of the light-emitting elements which is accumulated in the board of the light irradiating device and heat of the electric circuit which is accumulated in the drive board are absorbed by the heat-dissipating member and are dissipated to the outside.

### CITATION LIST

### Patent Literature

[Patent Literature 1] International Publication No. WO2014/034778

### SUMMARY

### Technical Problem

According to the light irradiating apparatus of Patent Literature 1, since the heat-dissipating member absorbs and dissipates heat of the light-emitting elements and heat of the drive board, it is possible to suppress an increase in temperature of the drive board while efficiently cooling the light-emitting elements. However, in the case of a configuration in which the entire light irradiating apparatus is housed in a single housing like the configuration of Patent Literature 1, there is a problem that since part of ultraviolet light from the light-emitting elements hits an inner surface of the housing and is also repeatedly reflected in the housing, the temperature of the housing itself increases. In addition, similarly, there is also a case where part of ultraviolet light caused by reflection from an outside (an irradiation target member such as paper) of the light irradiating apparatus hits the inner surface of the housing, causing an increase in temperature.

When the temperature of the housing becomes high as described above, it becomes difficult to conduct the work of maintaining the light irradiating apparatus or to dispose another apparatus or component near the light irradiating apparatus.

The present invention has been made in view of the above-described circumstances. Some embodiments provide a light irradiating apparatus which is capable of suppressing an increase in temperature of a housing by efficiently cooling a light-emitting element and a drive board while employing a configuration in which the entire light irradiating apparatus is covered with the housing.

### Solution to Problem

In order to achieve the above object, a light irradiating apparatus of one embodiment comprises: a light source module which includes a board and a light-emitting element mounted on a first surface of the board; a heat sink which is provided in contact with a second surface of the board; a circuit board or circuit wiring which is electrically connected to the light source module; and a housing which has a first space which houses the heat sink and a second space which houses the circuit board or circuit wiring, wherein the housing is provided with a first opening which connects the first space and an outside of the housing, a second opening which connects the second space and the outside of the housing, and a third opening which connects the first space and the second space.

The housing may have a partition wall which separates the first space and the second space, and the third opening be provided in the partition wall.

The heat sink may be disposed between the first opening and the third opening.

The circuit board or circuit wiring may be disposed between the second opening and the third opening.

The light irradiating apparatus may further comprise a dry air generator which generates dry air by reducing an amount of moisture in an inputted air and supplies the dry air thus generated to the first opening.

A flow passage through which a refrigerant selected from water, or ethylene glycol, propylene glycol, or a mixture thereof with water flows may be provided in the heat sink.

The circuit board or circuit wiring may be a member which supplies electric power to the light source module or controls the light source module.

The light-emitting element may emit light of a wavelength which acts on an ultraviolet curable resin.

According to some embodiments as described above, it is possible to achieve a light irradiating apparatus which is capable of suppressing an increase in temperature of a housing by efficiently cooling a light-emitting element and a drive board while employing a configuration in which the entire light irradiating apparatus is covered with the housing.

### BRIEF DESCRIPTION OF DRAWINGS

FIGS. 1A to 1E are diagrams for explaining an external appearance of a light irradiating apparatus according to an embodiment described herein.

FIG. 2 is a diagram for explaining an internal configuration of the light irradiating apparatus according to the embodiment described herein.

FIG. 3 is a diagram for explaining a configuration of a light irradiating unit mounted on the light irradiating apparatus according to the embodiment described herein.

FIG. 4 is a diagram for explaining an internal configuration of a heat sink mounted on the light irradiating apparatus according to the embodiment described herein.

### DESCRIPTION OF EMBODIMENT

Hereinafter, some embodiments of the present invention will be described in detail with reference to the drawings. Note that in the drawings, the same or corresponding portions are denoted by the same reference signs, and descriptions thereof are not repeated.

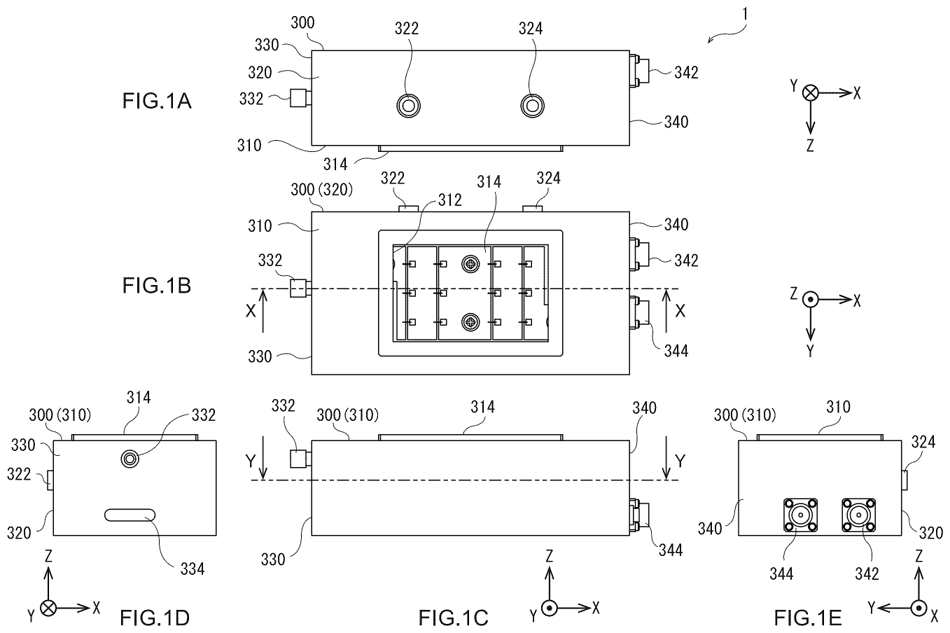

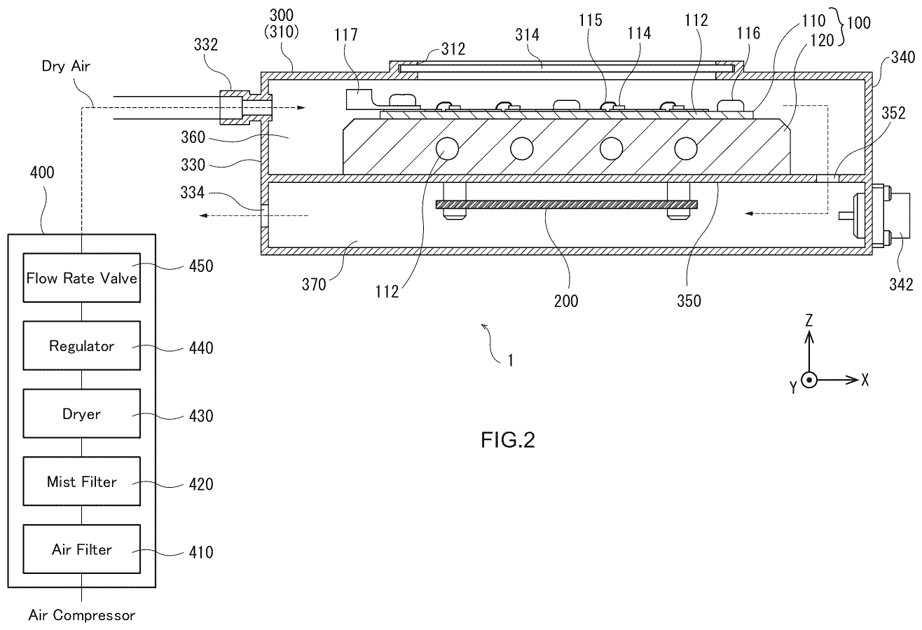

FIGS. 1A to 1E are diagrams for explaining an external appearance of a light irradiating apparatus 1 according to an embodiment described herein, and FIG. 1A is a top view, FIG. 1B is a front view, FIG. 1C is a bottom view, FIG. 1D is a left side view, and FIG. 1E is a right side view. In addition, FIG. 2 is a diagram for explaining an internal configuration of the light irradiating apparatus 1 according to the embodiment described herein and is a sectional view taken along line X-X of FIG. 1B. Note that FIG. 2 also schematically shows a configuration of a dry air generator 400 connected to the light irradiating apparatus 1, and a dashed line in FIG. 2 shows a flow of dry air generated in the dry air generator 400.

The light irradiating apparatus 1 of the present embodiment is an apparatus to be mounted on a light source apparatus which cures an ultraviolet curable ink used as an ink for printing or an ultraviolet curable resin used as a sealant for FPD (Flat Panel Display) and the like, and is disposed to face an irradiation target, which is not shown, and emits ultraviolet light toward a predetermined area of the irradiation target. Note that the light irradiating apparatus 1 of the present embodiment is connected to the dry air generator 400 and is configured such that the dry air generated in the dry air generator 400 is supplied into a housing 300 of the light irradiating apparatus 1.

As shown in FIGS. 1A to 1E and FIG. 2, the light irradiating apparatus 1 includes a light irradiating unit 100 which emits ultraviolet light, a control circuit board 200 (a circuit board or circuit wiring) which is electrically connected to the light irradiating unit 100, and the housing 300 which houses the light irradiating unit 100 and the control circuit board 200. Hereinafter, in the present Specification, description is made by defining a longer-side direction of ultraviolet light emitted from the light irradiating apparatus 1 (that is, a left-right direction of FIG. 1B) as an X-axis direction, a shorter-side direction of ultraviolet light (that is, an up-down direction of FIG. 1B) as a Y-axis direction, and a direction orthogonal to the X axis and the Y axis as a Z-axis direction.

The housing 300 is a case member made of aluminum, and as shown in FIGS. 1A to 1E, an opening 312 is formed in a front surface 310, and a window part 314 made of glass is attached to the opening 312. In addition, in an upper surface 320 of the housing 300, a supply port 322 and a discharge port 324 for a refrigerant are provided. In addition, in a left side surface 330 of the housing 300, an air inlet port 332 (a first opening) through which the dry air is supplied from the dry air generator 400 and an air outlet port 334 (a second opening) through which the air in the housing 300 is discharged are provided. In addition, in a right side surface 340 of the housing 300, power supply connectors 342 and 344 which are connected to an external power supply apparatus (not shown) and which supplies electric power to the control circuit board 200 are provided.

In addition, as shown in FIG. 2, inside the housing 300, a partition wall 350 which partitions the inside of the housing 300 into two spaces in the Z-axis direction is provided, and the partition wall 350 separates a first housing portion 360 (a first space) which houses the light irradiating unit 100 and a second housing portion 370 (a second space) which houses the control circuit board 200. In addition, in an end portion of the partition wall 350 in the X-axis direction, a through-hole 352 (a third opening) which connects the first housing portion 360 and the second housing portion 370 is provided, so that the dry air which has entered the housing 300 passes through the first housing portion 360 and is supplied to the second housing portion 370 via the through-hole 352 (the detail will be described later).

Note that in the present embodiment, the air inlet port 332 penetrates the left side surface 330 of the housing 300 to connect the first housing portion 360 and the outside of the housing 300, and the air outlet port 334 penetrates the left side surface 330 of the housing 300 to connect the second housing portion 370 and the outside of the housing 300.

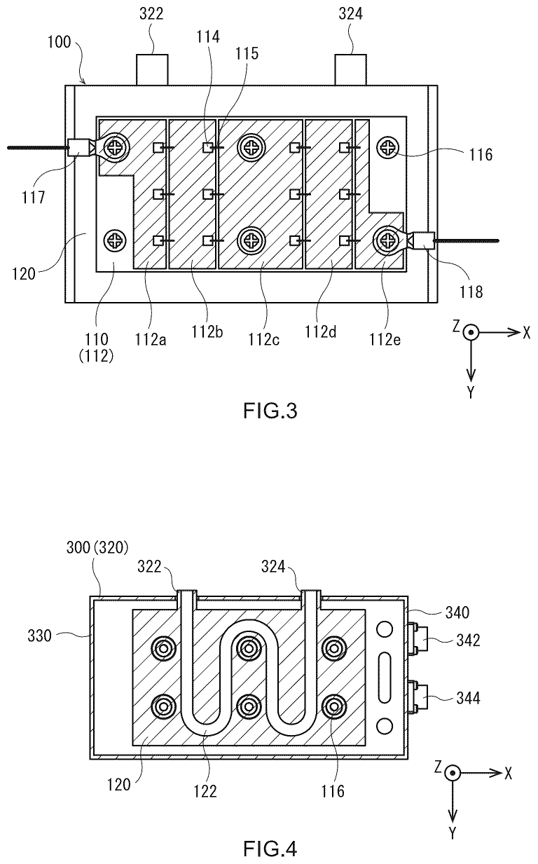

FIG. 3 is a plan view for explaining a configuration of the light irradiating unit 100. As shown in FIG. 3, the light irradiating unit 100 includes a light source module 110, a heat sink 120, and the like. The light source module 110 is a unit which emits ultraviolet light toward the irradiation target and irradiates a predetermined area of the irradiation target with the ultraviolet light in a rectangular shape, and is placed and fixed on the heat sink 120 in the present embodiment.

The light source module 110 includes a rectangular LED board 112 in which a plurality of wiring patterns 112a to 112e are formed, and a plurality of LED elements 114 (light-emitting elements) disposed on a surface (a first surface) of the LED board 112. As shown in FIG. 3, the light source module 110 of the present embodiment is fixed to the heat sink 120 by six fixing screws 116 which are inserted through the LED board 112. Note that as the LED board 112, a ceramic board formed of aluminum nitride having high thermal conductivity, or the like is preferably used.

The LED elements 114 are, for example, LED chips which emit ultraviolet light, and in the present embodiment, are disposed at predetermined intervals in the X-axis direction and the Y-axis direction in such a manner that three LED elements 114 are disposed on each of the wiring patterns 112a to 112d, that is, 4 (in the X-axis direction)×3 (in the Y-axis direction) in total. An anode terminal of each LED element 114 is die-bonded to the corresponding wiring pattern 112a to 112d directly below, and a cathode terminal of each LED element 114 is electrically connected to the adjacent wiring pattern 112b to 112e by a bonding wire 115. That is, in the present embodiment, three LED elements 114 arrayed in the Y-axis direction are electrically connected in parallel to each wiring pattern 112a to 112d, and the wiring patterns 112a to 112e are electrically connected in series by the bonding wires 115. In addition, an anode terminal 117 (positive electrode terminal) which is electrically connected to the control circuit board 200 (FIG. 2) is fastened together to the wiring pattern 112a by a fixing screw 116, and a cathode terminal 118 (negative electrode terminal) which is electrically connected to the control circuit board 200 is fastened together to the wiring pattern 112e by a fixing screw 116.

Note that the control circuit board 200 (FIG. 2) is a member which is electrically connected to an external power supply apparatus (not shown) via the power supply connectors 342, 344 and generates drive current for the LED elements 114 of the light source module 110 by using electric power from the power supply apparatus (that is, supplies the electric power to the light source module 110) or controls the drive current (that is, controls the light source module 110). The control circuit board 200 may be a circuit component in any of various forms such as an element shape besides a board shape, or may be a wiring member (circuit wiring) such as a wire.

As shown in FIG. 2, the control circuit board 200 of the present embodiment is disposed between the air outlet port 334 and the through-hole 352 and is fixed on the back surface side of the partition wall 350 (the surface opposite to the light source module 110). Note that in FIG. 2, wires connecting the control circuit board 200 and the power supply connectors 342, 344 and wires connecting the control circuit board 200 and the anode terminal 117 and the cathode terminal 118 are omitted for making the figure more visible.

As shown in FIG. 3, when drive current (that is, anode current) from the control circuit board 200 is supplied to the anode terminal 117 connected to the wiring pattern 112a, the drive current flows to all the LED elements 114 disposed on the wiring patterns 112a to 112d, and ultraviolet light in light intensity corresponding to the drive current is emitted from the LED elements 114. Note that the LED elements 114 of the present embodiment are configured such that the LED elements 114 have substantially the same electric characteristics and ultraviolet light in substantially the same irradiation intensity distribution is emitted from each LED element 114. The drive current which has flowed through each LED element 114 passes through the wiring pattern 112e, and return current (that is, cathode current) is returned from the cathode terminal 118 connected to the wiring pattern 112e toward the control circuit board 200.

When the drive current flows through all the LED elements 114 mounted on the light source module 110 and ultraviolet light is emitted from each LED element 114 in this way, the temperature is increased by self-heat generation of the LED elements 114, causing such a problem that the luminous efficiency significantly decreases. For this reason, in the present embodiment, the heat sink 120 is provided in tight contact with the light source module 110 to forcibly dissipate the heat generated in the LED elements 114.

The heat sink 120 is a member on which the light source module 110 is fixed, and which dissipates the heat generated in the light source module 110 and is formed from a metal such as copper having high thermal conductivity. As shown in FIG. 2 and FIG. 3, the heat sink 120 is a member having a rectangular plate-shape, and the front surface (surface on the + side in the Z-axis direction) of the heat sink 120 serves as a surface on which the light source module 110 is mounted (that is, which is in contact with the back surface (second surface) of the LED board 112) (FIG. 2, FIG. 3). In addition, as shown in FIG. 2, the heat sink 120 is disposed between the air inlet port 332 and the through-hole 352, and the bottom surface of the heat sink 120 is fixed to the partition wall 350 of the housing 300 by a plurality of fixing screws (not shown).

FIG. 4 is a diagram for explaining an internal configuration of the heat sink 120 and is a sectional view taken along line Y-Y of FIG. 1C. The heat sink 120 of the present embodiment is a so-called water-cooling heat sink, and as shown in FIG. 4, a cylindrical flow passage 122 through which a refrigerant flows is formed in such a manner as to meander from the supply port 322 to the discharge port 324 inside the heat sink 120. Note that as the refrigerant, water, or ethylene glycol, propylene glycol, or a mixture thereof with water is used.

As mentioned above, the present embodiment takes a configuration in which the light irradiating unit 100 is housed in the housing 300 as shown in FIG. 2. However, there is a problem that since part of ultraviolet light from the LED elements 114 hits an inner surface of the housing 300 and is also repeatedly reflected in the housing 300, the temperature of the housing 300 itself increases. In addition, in the case where the light irradiating apparatus 1 is used under an environment with high humidity, there is a problem that the air with high humidity cannot be prevented from entering the housing 300, and if the air with high humidity enters the housing 300 and comes into contact with the cooled heat sink 120 and the periphery thereof, condensation is generated. In addition, even in the case where the light irradiating apparatus 1 is not under an environment with high humidity, there is a problem that when the refrigerant flows through the heat sink 120 with the LED elements 114 being not on, the heat sink 120 and the periphery thereof are excessively cooled, generating condensation on the heat sink 120 and the periphery thereof. In view of this, in order to solve such problems, the light irradiating apparatus 1 of the present embodiment is configured such that dry air is generated by the dry air generator 400 and the dry air is supplied into the housing 300 in which the light irradiating unit 100, the heat sink 120, and the control circuit board 200 are housed. Note that the dry air from the dry air generator 400 is configured to be supplied into the housing 300 always (at least when the refrigerant flows through the heat sink 120 (that is, when the heat sink 120 is cooled)) irrespective of whether the LED elements 114 are on or off.

As mentioned above, the air inlet port 332 is provided in the left side surface 330 of the housing 300 of the light irradiating apparatus 1 of the present embodiment and the dry air generator 400 is connected to the air inlet port 332 (FIG. 2). Then, compressed air from an external air compressor (air supply apparatus) is forcibly supplied to the first housing portion 360 of the housing 300 through the dry air generator 400 and the air inlet port 332.

The dry air generator 400 of the present embodiment is an apparatus that generates dry air (that is, dehumidified air) from inputted compressed air, and includes an air filter 410, a mist filter 420, a dryer 430, a regulator 440, a flow rate valve 450, and the like as shown in FIG. 2.

The air filter 410 is a filter for removing foreign matters such as dust and dirt from compressed air inputted from the air compressor. The mist filter 420 is a filter for removing oil mist (fine particles) and the like contained in the compressed air which has passed through the air filter 410. The dryer 430 is an apparatus for drying the compressed air which has passed through the mist filter 420 (reducing the amount of moisture in the compressed air), and for example, a so-called refrigerant condenser configured by folding a metal pipe through which the refrigerant flows in a meandering manner, or the like is used. The regulator 440 is an apparatus for reducing the pressure of the compressed air which has passed through the dryer 430. The flow rate valve 450 is an apparatus for adjusting the flow rate of the compressed air to be supplied from the dry air generator 400 into the housing 300.

As the compressed air inputted into the dry air generator 400 flows through the air filter 410, the mist filter 420, the dryer 430, the regulator 440, and the flow rate valve 450 in this order in this way, dry air which is clean and dried is generated and supplied into the first housing portion 360 of the housing 300 via the air inlet port 332 with predetermined pressure and flow rate. Note that in the present Specification, the dry air means air having a lower humidity (having a lower amount of moisture) than the compressed air inputted into the dry air generator 400, and is, for example, air having a dew point of −20° or less (having an air humidity of 5% or less and an air temperature of 0° under an atmospheric pressure)).

As mentioned above, in the present embodiment, since the compressed air generated in the dry air generator 400 is forcibly supplied into the first housing portion 360 of the housing 300, the dry air supplied into the first housing portion 360 first flows through a space in which the light irradiating unit 100 (that is, the light source module 110 and the heat sink 120) is disposed in the first housing portion 360. Then, once the first housing portion 360 is filled with the dry air, the dry air in the first housing portion 360 is pushed into the second housing portion 370 from the through-hole 352 provided in the partition wall 350. Then, as the dry air in the first housing portion 360 is successively pushed into the second housing portion 370, the dry air supplied into the second housing portion 370 flows a space in which the control circuit board 200 is disposed and is discharged from the air outlet port 334 formed in the left side surface 330 of the housing 300.

In this way, the dry air generated in the dry air generator 400 is supplied into the first housing portion 360, flows inside the first housing portion 360 toward the through-hole 352 (that is, along the X-axis direction), flows from the through-hole 352 into the second housing portion 370, flows inside the second housing portion 370 toward the air outlet port 334 (that is, along a direction opposite to the X-axis direction), and is discharged to the outside. Note that in the present embodiment, since the flow rate is controlled such that the amount of the compressed air introduced into the first housing portion 360 of the housing 300 from the dry air generator 400 becomes larger than the amount of the dry air to be discharged from the air outlet port 334 to the outside, the first housing portion 360 and the second housing portion 370 are always filled with the dry air. Therefore, even if the air inside the first housing portion 360 (that is, the dry air) is cooled by the heat sink 120, no condensation is generated.

In addition, since the dry air in the first housing portion 360 is cooled by the heat sink 120 disposed in the first housing portion 360, the inside of the first housing portion 360 is filled with cooled dry air. As a result, the housing 300 itself is cooled by the cooled dry air with which the first housing portion 360 is filled, and even in the case where part of ultraviolet light from the LED elements 114 hits the inner surface of the housing 300 and increases the temperature of the housing 300, the housing 300 can be efficiently cooled.

In addition, since the dry air in the first housing portion 360 is cooled by the heat sink 120 disposed in the first housing portion 360, cooled dry air is supplied into the second housing portion 370. Hence, the control circuit board 200 disposed in the second housing portion 370 is efficiently cooled by the cooled dry air.

As described above, the light irradiating apparatus 1 of the present embodiment is configured such that the dry air from the dry air generator 400 is introduced into the housing 300, and the dry air always flows through the first housing portion 360 in which the light irradiating unit 100 (that is, the light source module 110 and the heat sink 120) is disposed and the second housing portion 370 in which the control circuit board 200 is disposed (at least when the refrigerant flows into the heat sink 120). Then, the configuration in which the periphery of the light irradiating unit 100 is filled with the dry air makes it possible to suppress or prevent the generation of condensation on the heat sink 120. In addition, the configuration in which the periphery of the control circuit board 200 is filled with the dry air cooled by the heat sink 120 suppresses an increase in temperature of the control circuit board 200. That is, the light irradiating apparatus 1 of the present embodiment is maintained such that the humidity inside the housing 300 (that is, the first housing portion 360 and the second housing portion 370) is always low and also the temperature does not increase while employing the configuration in which the light irradiating unit 100 (that is, the light source module 110 and the heat sink 120) and the control circuit board 200 are covered with the housing 300. Hence, according to the configuration of the present embodiment, the LED elements 114 on the LED board 112 do not short-circuit, the electronic components on the control circuit board 200 do not short-circuit, and the ion migration of the patterns on the LED board 112 and the control circuit board 200 is not accelerated, by water droplets formed by condensation. In addition, since the inside of the housing 300 is filled with cooled dry air, an increase in temperature of the housing 300 is also suppressed.

The above description is provided for explaining the embodiments of the present invention, but the present invention should not be limited to the configurations of the aforementioned embodiments, but may be modified in various ways within the scope of the technical idea.

For example, although the present embodiment has been described on the assumption that the inside of the housing 300 is divided into the first housing portion 360 which houses the light irradiating unit 100 and the second housing portion 370 which houses the control circuit board 200 by the partition wall 350, the configuration is not necessarily limited to such a configuration. The light irradiating unit 100 and the control circuit board 200 may be disposed in one housing portion in the housing 300. Note that in this case, it is preferable that dry air flow through the space in which the light irradiating unit 100 is disposed to the space in which the control circuit board 200 is dispose in this order.

In addition, although in the present embodiment, the dry air flows through the first housing portion 360 to the second housing portion 370 in this order, the configuration is not necessarily limited to such a configuration. The dry air may flow through the second housing portion 370 to the first housing portion 360 in this order (that is, in the opposite direction).

In addition, although in the present embodiment, the dry air is generated by the dry air generator 400, which is separated from the light irradiating apparatus 1, the dry air generator 400 may be incorporated integrally in the light irradiating apparatus 1.

In addition, as long as sufficiently dried compressed air can be supplied to the light irradiating apparatus 1, the dry air generator 400 is not necessarily required.

It should be noted that the embodiments disclosed herein should be considered to be exemplary and nonrestrictive in all respects. The scope of the present invention is specified not by the above description but by the scope of claims, and is intended to include all modifications within the meaning and scope equivalent to the scope of claims.

1. A light irradiating apparatus comprising:
a light source module which includes a board and a light-emitting element mounted on a first surface of the board;
a heat sink which is provided in contact with a second surface of the board;
a circuit board or circuit wiring which is electrically connected to the light source module; and
a housing which has a first space which houses the heat sink and a second space which houses the circuit board or circuit wiring, wherein
the housing is provided with a first opening which connects the first space and an outside of the housing, a second opening which connects the second space and the outside of the housing, and a third opening which connects the first space and the second space.

2. The light irradiating apparatus according to claim 1, wherein
the housing has a partition wall which separates the first space and the second space, and
the third opening is provided in the partition wall.

3. The light irradiating apparatus according to claim 1, wherein the heat sink is disposed between the first opening and the third opening.

4. The light irradiating apparatus according to claim 1, wherein the circuit board or circuit wiring is disposed between the second opening and the third opening.

5. The light irradiating apparatus according to claim 1, further comprising a dry air generator which generates dry air by reducing an amount of moisture in an inputted air and supplies the dry air thus generated to the first opening.

6. The light irradiating apparatus according to claim 1, wherein a flow passage through which a refrigerant selected from water, or ethylene glycol, propylene glycol, or a mixture thereof with water flows is provided in the heat sink.

7. The light irradiating apparatus according to claim 1, wherein the circuit board or circuit wiring is a member which supplies electric power to the light source module or controls the light source module.

8. The light irradiating apparatus according to claim 1, wherein the light-emitting element emits light of a wavelength which acts on an ultraviolet curable resin.
